(19) United States
(12) Patent Application Publication
(10) Pub. No.: US 2025/0061942 A1
(43) Pub. Date: Feb. 20, 2025

(54) DEVICE AND METHOD FOR INFORMATION PROCESSING

(71) Applicant: Helmholtz-Zentrum Dresden Rossendorf E.V, Dresden (DE)

(72) Inventors: Helmut SCHULTHEISS, Dresden (DE); Katrin SCHULTHEISS, Dresden (DE); Lukas KÖRBER, Dresden (DE); Kilian LENZ, Dresden (DE)

(21) Appl. No.: 18/721,698

(22) PCT Filed: Dec. 20, 2022
(86) PCT No.: PCT/EP2022/086852

§ 371 Date: Jun. 19, 2024

(30) Foreign Application Priority Data
Dec. 21, 2021 (DE) 10 2021 214 772.0

(51) Int. Cl. G11C 11/54; G11C 11/16

(52) U.S. Cl. CPC G11C 11/54; G11C 11/161

(57) ABSTRACT

A device for information processing with a magnon reservoir made of a material with spontaneous magnetic order, in which two-dimensional quantized magnon states are present, an input unit and an output unit. The input unit is configured to generate an energy input provided with a temporal pattern in the magnon reservoir as input information, so that non-linear magnon scattering processes are excited, a resulting magnon spectrum being predetermined by the energy input provided with a temporal pattern and the three-dimensional dimensions of the magnon reservoir, and the output unit is configured to detect the resulting magnon spectrum as output information.

The present invention relates to a device and a method for information processing.

Existing technologies for information processing and information storage are increasingly reaching their limits in the field of machine learning and neural networks. Typically, attempts are made to meet the increased technical demands on hardware components in the field of artificial intelligence with a high degree of parallelization and a large number of computing cores. In this regard, integrated, non-volatile memory elements such as MRAM (magnetic random access memory) are also an essential part. There are also solution approaches that aim to move away from traditional electronics and enable new ways of transmitting information, for example by means of spin wave transport. US 2009/00960044 A1 discloses a corresponding device in which information is to be transmitted by a spatial transport of spin waves.

For the realization of circuits for use in the field of artificial intelligence, attempts are being made to implement artificial neural networks with CMOS-compatible circuits (complementary metal-oxide-semiconductor). However, there are two fundamental disadvantages here: On the one hand, this results in an enormous overhead, which in extreme cases can even lead to large parts of the circuit or chip not contributing to the intended pattern recognition, but still being supplied with energy. Although the neural network can be thinned out at chip level to minimize this problem, this also means that the respective chip can only be used for a single specific application. As the learning and optimization process of neural networks in particular requires large amounts of energy, this solution is not economical in the long term.

On the other hand, most of the energy consumed during data processing is used to move data between different memory modules, which results in a high loss of energy due to data movement, especially when realizing artificial neural networks (which are based on massive interlinking and parallelism of the individual arithmetic units). In addition, the large number of electrical connections required to establish the necessary interlinking makes them extremely difficult to integrate.

The present invention is therefore based on the object of proposing a device which avoids the aforementioned disadvantages, i.e. which enables energy-efficient information processing.

According to the invention, this object is attained by a device and a method according to the independent claims. Advantageous embodiments and further developments are described in the dependent claims.

A device for information processing has a magnon reservoir made of a material with spontaneous magnetic order, in which two-dimensional quantized magnon states are present, an input unit and an output unit. The input unit is configured to generate an energy input provided with a temporal pattern as input information in or at the magnon reservoir, so that non-linear magnon scattering processes are excited, a resulting magnon spectrum being predetermined by the energy input provided with a temporal pattern and the three-dimensional dimensions of the magnon reservoir, and the output unit being configured to detect the resulting magnon spectrum as output information.

The device is therefore configured to introduce input information into the magnon reservoir in the form of an energy input, for example a pulsed energy input, and to generate well-defined cascades of scattering processes there depending on the temporal sequence of the input information. Temporally coded patterns in the input information lead to different, well-defined responses in the magnon spectrum due to the nonlinear interaction, i.e. the output information enables a clear classification of the input information. Nonlinear scattering of magnons, also known as spin waves, in time and space stimulated by other magnons fulfils the requirements for separation, approximation and short-term memory, especially with regard to neuromorphic hardware. Spin waves are collective excitations of the magnetic moments in a magnetically ordered system, which are caused by the long-range dipole-dipole interaction and the short-range exchange interaction. The respective quanta are referred to as magnons.

Since the use of the magnon reservoir does not result in interlinking in the real space, the local space, but in nonlinear scattering between fully quantized, magnonic eigenstates of a magnetically ordered microstructure in the reciprocal space, the k-space, not only is the interlinking problem elegantly solved, but a higher integration or scalability can also be achieved. In contrast to previous solutions based on semiconductors, this is not achieved by further miniaturization, which entails additional process difficulties in the manufacture of ever smaller structures, but instead an increased complexity or sophistication and range or bandwidth can be achieved by increasing the size of the components. By operating in reciprocal space, increased sophistication and range is achieved by enlarging the components, i.e. the magnon reservoirs. Since there is no transport of particles carrying mass, but a change of magnetic states is carried out, a practically unlimited number of operations can be carried out and a large tunability and optimization of purely magnetic parameters (which are reprogrammable) is possible. Thus, due to the spatial-temporal delocalization of the magnons in the magnon reservoir serving as a resonator, there are no transport losses, as a result of which no interference effects occur and there is no phase relevance, and scalability is facilitated.

Since there is a two-dimensional quantization of the spin waves within the sample plane, i.e. within the magnon reservoir or the magnon cavity, spatial transport is avoided and the interaction takes place entirely through transitions in reciprocal space, i.e. there are no transport losses in real space. The complete quantization of spin wave resonances also enables a much stronger interaction through scattering processes by reducing the states. Secondary energy levels can be occupied more easily and lead to lower thresholds for non-linear phenomena. The device is also easy to manufacture using existing technology and is fully compatible with existing CMOS processes.

A material with spontaneous magnetic order is to be understood here in particular as a ferromagnetic or ferrimagnetic material at room temperature, i.e. 20° C. The generated magnon scattering processes are typically higher-order magnon scattering processes. A higher-order magnon scattering process is to be understood in particular as three-magnon scattering and four-magnon scattering, i.e. cases in which two magnons are generated from one magnon or one magnon is generated from two magnons (three-magnon scattering) or two magnons with changed frequencies and/or changed wave vectors are generated from two magnons. Higher-order processes are advantageous for the purpose of application, but are usually not dominant.

A soft magnetic material can be used as the material for the magnon reservoir, i.e. in particular a material whose coercive field strength is less than 1000 A/m. Typically, a metallic material is used, but alternatively a ceramic material, i.e. in particular a ferrite, can also be used. A nickel-iron alloy known as ‘permalloy’ or ‘mu-metal’ is particularly preferred as the metallic material, i.e. an alloy with a nickel content of between 72 percent and 82 percent and an iron content of between 18 percent and 28 percent. If this alloy is not made exclusively of nickel and iron, other elements such as copper, chromium or molybdenum can be added, whereby these can be added in a proportion of between 2 percent and 5 percent. However, Ni₈₁Fe₁₉ or Ni₇₈Fe₂₂ is typically used.

In further embodiments, a cobalt-iron alloy, i.e. CoFe, a cobalt-iron-boron alloy (CoFeB) or a Heusler alloy (i.e. a ferromagnetic alloy whose individual components are not ferromagnetic in themselves) can also be used as the material for the magnon reservoir.

The magnon reservoir or the magnonic reservoir is typically designed as a disc, an ellipse, a ring or a rectangle, as corresponding geometric shapes are easy to produce. The height of the magnon reservoir is usually a maximum of 10 percent of its maximum length and/or width and/or diameter, i.e. it is essentially a two-dimensional magnon reservoir. The height is preferably a maximum of 100 nm in order to create a sufficiently small structure.

It may be provided that the magnon reservoir is magnetized in a vortex state, i.e. a state in which the magnetization is characterised by a concentric alignment of the magnetic moments. In this state, there is a well-defined and temporally stable magnetization in which scattering processes can still be excited efficiently without the need for an external magnetic field.

The input unit can be designed as a microwave antenna, in particular a microwave stripline, or as a laser radiation source that emits a pulsed laser beam or as a pulsed laser beam. The ability of the input unit to ensure magnon scattering processes through energy input into the magnon reservoir is fundamental and can be achieved both by microwave pulses and by pulsed laser irradiation with pulse durations typically in the range of up to 100 fs. However, the range can also extend from 100 attosecond long laser pulses to 10 picosecond long laser pulses. If a microwave antenna is used, it is also possible to place several magnon reservoirs directly on the microwave antenna, i.e. to bring them into direct contact with each other, so that an efficient energy input is made possible and several magnon reservoirs receive an energy input almost simultaneously.

The output unit can be designed as a magnetoresistive sensor in order to reliably and quickly detect the resulting magnon spectrum. In particular, the output unit can be designed as an anisotropic magnetoresistance sensor (AMR), a giant magnetoresistance sensor (GMR) or a tunnel magnetoresistance sensor (TMR). It is also possible that the output unit has several measuring sensors, i.e. a multi-part structure, which are designed to measure a spatially resolved magnon spectrum and are arranged at different positions in the magnon reservoir.

A non-volatile stray field generator can also be provided on the magnon reservoir to locally change the direction or influence the magnetization of the magnon reservoir. This allows a desired magnetization to be set in a targeted manner, whereby structures made of a material that has a higher coercive field strength than the material of the magnon reservoir and which are spatially separated from the magnon reservoir can serve as a stray field generator, for example, and influence the magnetization of the magnon reservoir through its stray field. In particular, geometric structures can be used in which one tip points in the direction of the magnon reservoir.

In a method for information processing, an input unit in a magnon reservoir made of a material with spontaneous magnetic order, in which two-dimensional quantized magnon states are present, generates an energy input provided with a temporal pattern as input information, so that non-linear magnon scattering processes are excited. A resulting magnon spectrum is predetermined by the energy input provided with a temporal pattern and the three-dimensional dimensions of the magnon reservoir, and an output unit detects the magnon spectrum as output information.

In addition, it may be provided that the pulsed energy input provided with the temporal pattern has a frequency, for example a carrier frequency, which corresponds to one of the resonance conditions of the magnon reservoir, as this stimulates scattering processes in a particularly efficient manner.

The method described is typically carried out using the device described, i.e. the device described is designed to carry out the method described.

The described device and/or method is typically used for an (artificial) neural network, machine learning, in particular reservoir computing, and/or neuromorphic computing and pattern recognition and/or classification.

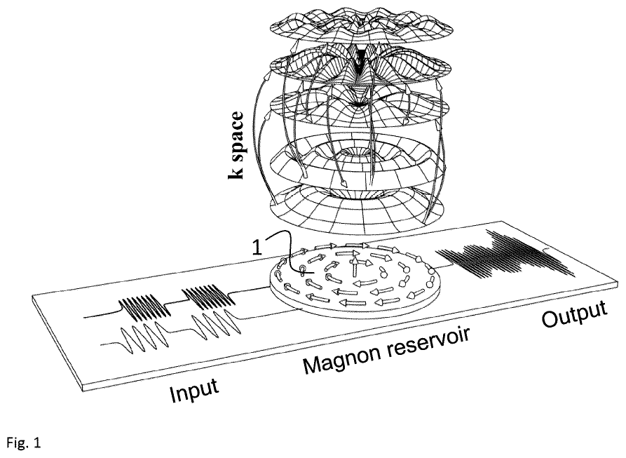

Exemplary embodiments of the invention are shown in the drawings and are explained below with reference to FIGS. 1 to 8.

In the figures:

FIG. 1 is a schematic view of the operation of a device for magnonic information processing;

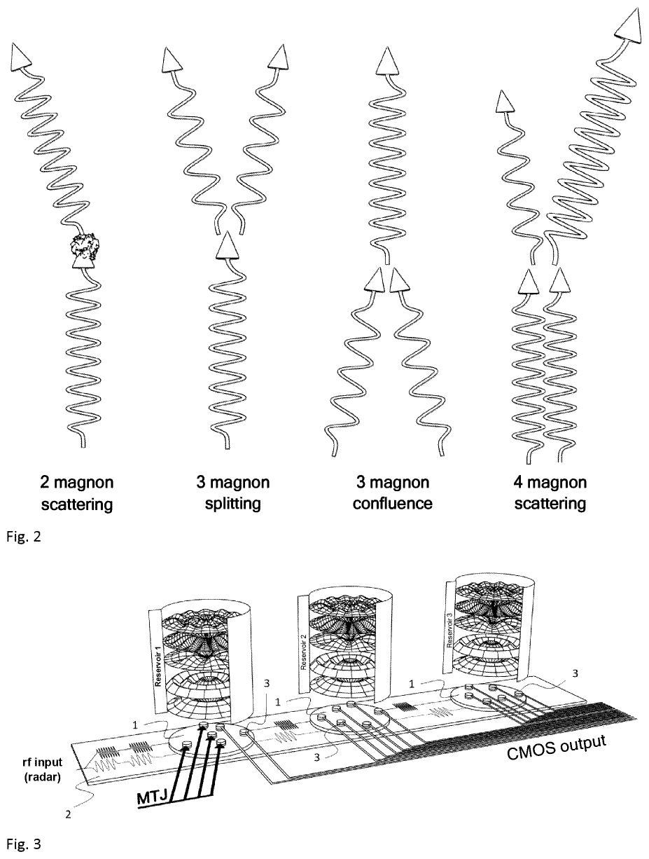

FIG. 2 is a schematic diagram of magnon scattering processes;

FIG. 3 a perspective schematic view with several magnon reservoirs on a microwave stripline;

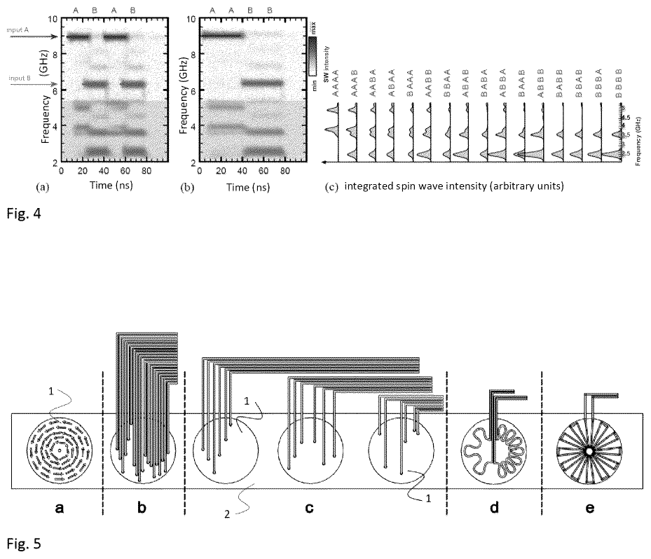

FIG. 4 is a schematic view of a resulting magnon spectrum including classification;

FIG. 5 is a perspective schematic view of the microwave stripline with several magnon reservoirs and different arrangements of output units;

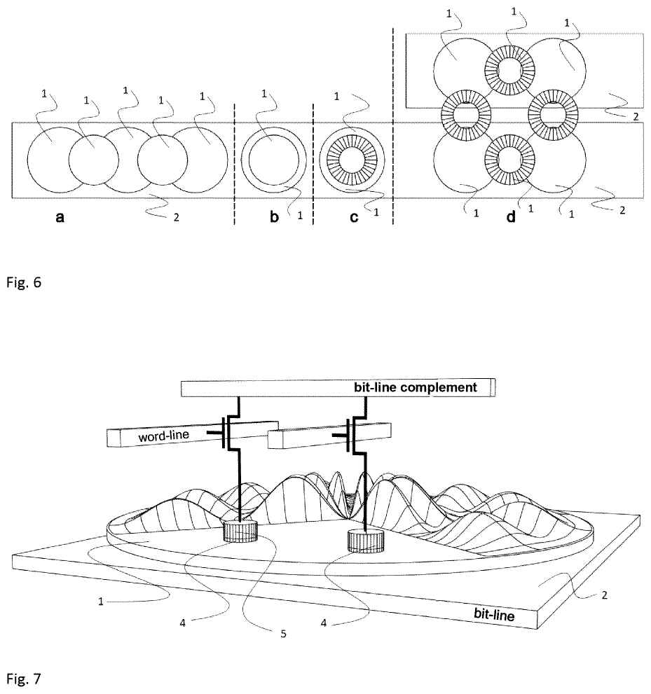

FIG. 6 is a view of several vertically stacked magnon reservoirs corresponding to FIG. 5;

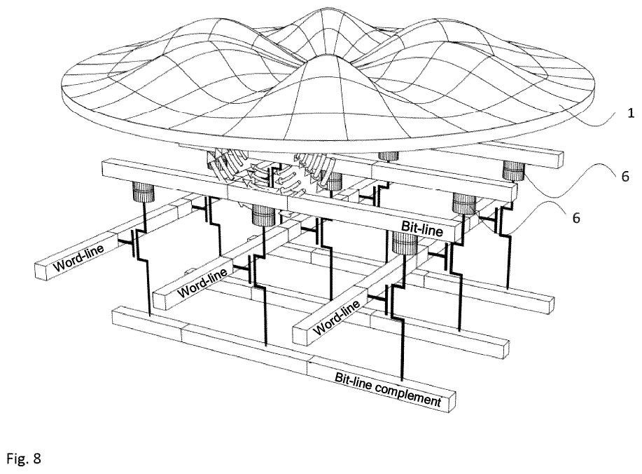

FIG. 7 is a schematic view of a TMR structure with magnon reservoir and

FIG. 8 is a view of a further exemplary embodiment of the memory structure corresponding to FIG. 7.

FIG. 1 shows a schematic view of the operation of a device for magnonic information processing, in which a magnon reservoir 1 in the form of a flat disc made of a soft magnetic material such as permalloy (Ni₈₀Fe₂₀), Co₂₅Fe₇₅ or CoₓFe_{y}B_{z} (with x, y, z=40, 40, 20; 60, 20, 20 or 20, 60, 20) is applied to an input unit 2 designed as a microwave stripline. The magnon reservoir 1 is magnetized in the vortex state, i.e. the magnetization is concentric within the plane of the disc and only points out of the sample plane at the center of the disc. Due to the ferromagnetic order and spatial constraint, two-dimensional quantized magnons are present in the magnon reservoir 1, i.e. the mode distributions shown as an example above the magnon reservoir 1 are formed in the reciprocal space, the k-space. In further exemplary embodiments, the magnetization does not have to lie predominantly in the sample plane (in-plane), but elements magnetized perpendicular to the structural plane (out-of-plane) can also be used.

A pulsed microwave signal is used as the input signal in the illustrated exemplary embodiment, in which two different microwave frequencies are irradiated as an example and stimulate corresponding magnon scattering processes, in particular three-magnon scattering, in the magnon reservoir 1. In further exemplary embodiments, the input signal can also be a broadband microwave signal as an analogue input signal, i.e. it does not necessarily have to be pulsed. For example, a broadband microwave signal can be used as input information for a radar Doppler sensor. The temporal pattern, i.e. the sequence of pauses between the pulses and pulses, and the selected microwave frequencies can be adjusted, but the microwave frequencies generally correspond to the resonance frequencies of the magnons for particularly efficient excitation of magnon scattering processes, which result in particular from the dimensions of the magnon reservoir. The power of the microwave pulses can also be adjusted, but should be selected in such a way that the non-linear processes mentioned are triggered, and depends accordingly on parameters such as the magnetic material used and the dimensions of the magnon reservoir 1. The controlled external excitation of scattering processes initiates a cascade of scattering processes, which is exemplarily illustrated by the arrows. The obtained output information is a magnon spectrum that is detected by a readout unit or output unit, which enables the input information to be clearly classified, for example for pattern recognition.

Instead of a circular disc, an ellipse, a ring, a rectangle, a pentagon, a hexagon or another polygonal shape can also be used as magnon reservoir 1 in further embodiments, whereby the thickness of the magnon reservoir is in the nanometer range and typically does not exceed 100 nm. Since the magnon reservoir 1 is essentially two-dimensional, a height is preferably a maximum of 10 percent of the value of the diameter, the maximum length or the maximum width. In addition, combinations of two-dimensionally constrained resonators and magnon conductors with only one-dimensional constraints are also possible, which enable the non-linear components to be interlinked in real space.

Instead of a microwave antenna or microwave stripline, a pulsed laser, i.e. a laser radiation unit that emits a pulsed laser beam, can also be used in further embodiments. Preferably, a laser radiation unit is used which irradiates the magnon reservoir at least partially with laser pulses with a pulse duration in the femtosecond range, i.e. laser pulses with a maximum pulse duration of 100 fs to 200 fs.

The spin wave spectrum obtained can be read out by a magnetoresistive sensor, for example a giant magnetoresistance sensor. In further exemplary embodiments, however, an anisotropic magnetoresistance sensor or a tunnel magnetoresistance sensor can also be used. The output unit 3 typically has several sensor units that are distributed on or around the magnon reservoir 1 so that a spatially resolved spin wave spectrum can be obtained.

FIG. 2 shows a schematic view of spin wave scattering processes. Recurring features are labelled with identical reference symbols in this figure and in the following figures. In the case of pure two-magnon scattering (FIG. 2a), the incident magnon retains its energy, but the wave vector changes due to the scattering, for example at a defect. In three-magnon scattering, an incident magnon decays into two magnons, each with half the frequency (splitting, FIG. 2b) or two magnons merge to form a single magnon confluence (FIG. 2c). Finally, FIG. 2d) shows the case of four-magnon scattering, in which two incident magnons of the same energy are scattered into two magnons of different energies.

FIG. 3 shows a schematic perspective view of a microwave stripline as input unit 1, on which several magnon reservoirs 1 are arranged. In the examplary embodiment shown, the magnon reservoirs 1 are again disc-shaped and arranged directly on the microwave stripline, which can be made of copper or gold, for example. The dimensions of the magnon reservoirs 1 are identical, and all magnon reservoirs 1 are made of the same material. In further exemplary embodiments, however, it is also possible for at least one of the magnon reservoirs 1 to be made of a different material. The three-dimensional dimensions of at least one of the magnon reservoirs 1 can also differ from the others. The diameter of each of the magnon reservoirs in the exemplary embodiment shown in FIG. 3 corresponds to just 99 percent of a width of the microwave stripline, but can also be up to 10 percent less than a width of the microwave stripline in further exemplary embodiments. Several sensors are formed above each of the magnon reservoirs 1, which together form the respective output unit 3. In the exemplary embodiment shown in FIG. 3, these sensors are designed as magnetic tunnel junctions, MTJ, and are placed in any arrangement on the top of the respective magnon reservoir 1. In particular, it is not necessary to provide an identical arrangement of sensors on each of the magnon reservoirs 1.

The sensors are configured to feed the detected signal via a conventional CMOS structure for further processing, for example as an input signal for a conventional arithmetic unit such as a computer, which can also graphically display the output information obtained from the magnon reservoir 1 and output it on a display unit such as a monitor.

The described device or a method using this device for information processing thus essentially relates to hardware for artificial intelligence based on the excitations of ferromagnetic or ferrimagnetic microstructures. Particularly in the field of reservoir computing (i.e. a non-linear, higher-dimensional system that serves as a reservoir, typically for processing time series) for processing large data streams close to the sensor (for example in edge computing or in the Internet of Things), magnonic components based on machine learning concepts for pattern recognition and classification (or also for predicting trajectories in highly non-linear systems) allow a significant reduction in energy consumption and an acceleration of data throughput. Applications range from the recognition of gestures, speech, text and images to the detection and prediction of potential collisions based on radar sensors in the field of autonomous driving. The information to be classified is provided as input information in the form of a pulsed electromagnetic wave and the output information obtained from the magnon reservoir 1 is subsequently used for classification, in that each output information obtained can be clearly assigned to a specific input structure by the magnon spectrum. This is typically done by a conventional computer, which can also be part of the device described. In this case in particular, the magnon reservoir 1 is used, for example in reservoir computing, to separate different patterns from one another in higher-dimensional space, i.e. to strongly separate them. A conventional computer, which is not based on magnon-based information processing or computing power, then takes over the task of interpreting the output signal of the magnon reservoir 1. With regard to scalability, ultimately only the coherence length of the magnons needs to be taken into account as a boundary condition, since standing waves are formed in the magnon reservoir 1 itself.

Intrinsically, the three main requirements for reservoir computing, namely separation, approximation and short-term memory, are fulfilled in a simple system that is compatible with existing semiconductor technology. In comparison with alternative approaches in the field of reservoir computing, the device described operates directly in the microwave range, i.e. typically in the range from 0.5 GHz to 200 GHz, preferably in the range from 1 GHz to 40 GHZ, is compatible with analogue and digital microwave signals as input data and thus also manages without energy-intensive (and process-slowing) digital-to-analogue converter stages and signal processing. However, the magnons (and corresponding energy inputs by the input unit) can also exist in the low THz range, for example up to 1.5 THz. Since the non-linear coefficients are stronger compared to other physical systems, the threshold for non-linear reactions is exceeded at much lower input powers. Since only a small part of the energy of the microwave antenna is absorbed by a single magnon reservoir 1, the same microwave stripline as an input unit can supply a large number of magnon reservoirs 1, i.e. several hundreds to thousands of magnon reservoirs 1.

This is made possible by the non-linear scattering processes and energetic transitions between magnon eigenstates in reciprocal space, which enable a denser state matrix the larger the magnetic elements used, which significantly reduces the requirements for lithographic production of the corresponding components and the associated costs.

FIG. 4 shows intensity profiles of the respective spin wave spectra or magnon spectra plotted against time in Figure a). An input signal of 8.9 GHz (input A) and an input signal of 6.3 GHz (input B) result in the spectrum shown in the time sequence ABAB, while a clear difference can already be seen in the sequence AABB in FIG. 4b). Finally, FIG. 4c) shows the integrated spin wave intensities in arbitrary units measured at different frequencies for different signal sequences. Recognizably, each signal sequence as a different input signal results in a clearly distinguishable output signal, so that 4-bit pulse sequences can be classified on the basis of the spin wave spectrum obtained in the sense of an assignment of the respective output signal to a single input signal.

The microwave antenna (or another input unit) excites magnons, which suddenly decay into two secondary magnons by three-magnon scattering processes when a certain microwave power is exceeded. This splitting of a single magnon into two spin waves with different frequencies is a direct consequence of the non-linearity of the underlying equations of motion, whereby the three-magnon scattering can be controlled by additionally excited spin waves.

FIG. 5 shows a perspective schematic view of the microwave stripline as an input unit 2 with several magnon reservoirs 1 and different arrangements of output units 3. The magnon reservoirs 2 shown are again magnetized in the vortex state, as shown again in FIG. 5a), and form part of a tunnel magnetoresistance element, whereby the upper part is again distributed in a random arrangement on the vortex disc as an output unit 3. Magnon reservoirs 1 with the same diameter and the same height show identical scattering processes with the same input information, i.e. have identical profiles or magnon spectra. This means that more tunnel magnetoresistance structures can be distributed and used to measure small signals and certain modes more efficiently. Figure 5b) shows an example of such a sensor arrangement. As shown in FIG. 5c), individual modes can also be specifically detected by suitable arrangement of the sensors, whereby sensors based on spin pumping or the inverse spin Hall effect are used in particular instead of the tunnel magnetoresistance effect in order to detect magnons through electrical voltages. Alternatively, the meandering microwave antennas shown in FIG. 5d) are also possible, which are arranged on the surface of one of the magnon reservoirs 1 and allow an inductive, mode-selective measurement. Another possible output unit 3 is a combination of strips of heavy metals with alternating signs of the spin Hall angle (e.g. tantalum and palladium), as shown in FIG. 5e). This can be used to generate a rectified voltage that is proportional to the spin wave amplitude. A practically random distribution of sensor elements as an output unit, such as MRAM elements, for reading out the spin wave states and the distribution over many identical magnetic structures enables a better signal-to-noise ratio. Furthermore, a coupling of the output unit 3 and its efficiency in measuring the spin wave intensity can be conceptually interpreted as part of the reservoir and precise knowledge of the distribution is not necessary as long as the distribution is only sufficiently random. Even failures of some sensor elements are irrelevant, which simplifies the manufacturing process enormously.

FIG. 6 also shows several embodiments of magnon reservoirs 1 arranged one above the other in a view corresponding to FIG. 5. The sensor elements arranged on the surface of the uppermost magnon reservoir 1 are not shown for reasons of simplicity. FIG. 6a) shows an arrangement in which, in addition to the repeated arrangement of identical structures on the microwave stripline, magnon reservoirs 1 are now also stacked overlapping in the vertical direction. FIG. 6b) shows an arrangement in which a further disk-shaped magnon reservoir 1, which has a smaller diameter than the lowest magnon reservoir 1, is concentrically stacked on a disk-shaped magnon reservoir 1. FIG. 6c) shows a corresponding arrangement with a concentrically stacked ring-shaped magnon reservoir 1 of the same diameter as the one shown in FIG. 6b). Overlapping structures can also be used for resonant coupling of magnon reservoirs across several striplines 2, as shown in FIG. 6d) as an example. By an alternating arrangement of vertically stacked but laterally slightly offset and overlapping elements, magnonically crosslinked chains can be generated, which leads to an increased sophistication of the magnon reservoir 1 and enables an adaptation to specific requirements for various classification problems, e.g. handwriting recognition. A triangular stray field generator arranged next to one of the magnon reservoirs 1, in which one of the corners points towards the center of the magnon reservoir 1, also allows a defined magnetic stray field to exist, which defines or at least influences the magnetization of the magnon reservoir 1.

FIG. 7 shows a schematic diagram of an exemplary embodiment in which a magnetic tunnel junction (MTJ) serves as a magnet sensor. The magnon reservoir 1 is the free layer of the magnetic tunnel junction and a tunnel barrier 4 and a reference layer 5 with fixed magnetization are applied as the sensor unit. The magnon reservoir 1 is located on a bit-line, the reference layer 5 is connected to a word-line and a bit-line complement.

FIG. 8 shows another example in which the magnon reservoir 1 is part of a magnetic tunnel junction serving as a magnon sensor or output unit 3. The dynamic magnetic field below the magnon reservoir 1, indicated by the arrows and caused by the magnons, is detected by external magnetic tunnel junctions 6. The exemplary readout mechanisms are directly compatible with CMOS logic and amplifier modules for electronic coupling and further processing. Electrical connectivity and compatibility with existing technology can also be realized by nanostructures (i.e. structures with dimensions of up to 500 nm, preferably up to 300 nm) with strong spin-orbit interaction (e.g. platinum, tantalum, tungsten or generally metal with a high atomic number, i.e. in particular an atomic number that is higher than that of tantalum) and inductive meandering microwave antennas with periodicities matched to the magnon profiles, as shown in FIG. 5d) as an example.

Features of the various embodiments disclosed in the exemplary embodiments only can be combined with each other and claimed individually

1-12. (canceled)

13. A device for information processing, comprising:
a magnon reservoir made of a material with spontaneous magnetic order, in which two-dimensional quantized magnon states are present,
an input unit and
an output unit, wherein
the input unit is configured to generate in the magnon reservoir an energy input provided with a temporal pattern as input information, so that non-linear magnon scattering processes are excited, a resulting magnon spectrum being predetermined by the energy input provided with a temporal pattern and the three-dimensional dimensions of the magnon reservoir, and
the output unit is configured to detect the resulting magnon spectrum as output information.

14. The device according to claim 13, wherein the magnon reservoir is formed as a disc, an ellipse, a ring or a rectangle and has a height which is at most 10 percent of its maximum length and/or width or its diameter and is at most 100 nm.

15. The device according to claim 13, wherein the magnon reservoir is magnetized in a vortex state.

16. The device according to claim 13, wherein the input unit is designed as a microwave antenna or as a pulsed laser.

17. The device according to claim 13, wherein the output unit is designed as a magnetoresistive sensor, an anisotropic magnetoresistance sensor, giant magnetoresistance sensor or tunnel magnetoresistance sensor.

18. The device according to claim 17, wherein the output unit has a plurality of measuring sensors which are configured to measure a spatially resolved magnon spectrum and are arranged at different positions of the magnon reservoir.

19. The device according to claim 13, wherein a non-volatile stray field generator is arranged on the magnon reservoir for locally changing the direction of the magnetization of the magnon reservoir.

20. The device according to claim 13, wherein the magnon reservoir is made of a soft magnetic material.

21. The device according to claim 13, wherein the magnon reservoir is made of a metallic material.

22. A method for information processing, in which an input unit in a magnon reservoir made of a material with spontaneous magnetic order, in which two-dimensionally quantized magnons are present, generates an energy input provided with a temporal pattern as input information, so that non-linear magnon scattering processes of higher order are excited, wherein a resulting magnon spectrum is predetermined by the energy input provided with a temporal pattern and the three-dimensional dimensions of the magnon reservoir, and an output unit detects the magnon spectrum as output information.

23. The method according to claim 22, wherein the energy input provided with a temporal pattern has a frequency which corresponds to one of the resonance frequencies of the magnon reservoir.

24. Use of the device according to claim 13 for a neural network, machine learning, reservoir computing, and/or neuromorphic computing.

25. Use of the method according to claim 22 for a neural network, machine learning, reservoir computing, and/or neuromorphic computing.
